(19) United States
(12) Patent Application Publication
(10) Pub. No.: US 2008/0064214 A1
(43) Pub. Date: Mar. 13, 2008

(54) SEMICONDUCTOR PROCESSING INCLUDING ETCHED LAYER PASSIVATION USING SELF-ASSEMBLED MONOLAYER

(75) Inventors: Taejoon Han, San Ramon, CA (US); Sang-Jun Cho, Pleasanton, CA (US); Sung-Jin Cho, Fremont, CA (US); Tom Choi, Santa Clara, CA (US); Prabhakara Gopaladasu, Fremont, CA (US); Sean Kang, San Ramon, CA (US)

Correspondence Address: BEYER WEAVER LLP, P.O. BOX 70250, OAKLAND, CA, 94612-0250, US

(73) Assignee: LAM RESEARCH CORPORATION, Fremont, CA (US)

(21) Appl. No.: 11/531,418

(22) Filed: Sep. 13, 2006

(51) Int. Cl. H01L 21/311; H01L 21/461

(52) U.S. Cl. 438/702; 438/706; 438/710; 438/714

(57) ABSTRACT

In the fabrication of an integrated circuit where a porous silicon oxide layer is formed over a surface of a semiconductor substrate to electrically isolate two conductive metal layers, a via through the porous silicon oxide layer has an opening etched through the porous silicon oxide layer, a self-assembled monolayer adhering to an etched surface of the opening and to exposed pores, and a conductive material filling the opening.

### BACKGROUND OF THE INVENTION

This invention relates generally to semiconductor processing, and more particularly the invention relates to surface passivation of exposed material following processing such as plasma etching.

Current integrated circuits include a silicon substrate in which transistors and other circuit devices are fabricated and a plurality of metal interconnect layers stacked over a surface of the substrate with a dielectric separating each interconnect layer. To meet the requirements posed by 45 nanometer design rules, a low k insulator is required. A porous silicon oxide material is presently employed as the low k dielectric, and may include porous organo-silicate-glass (OSG) materials. OSG materials may be silicon dioxide containing organic component such as methyl groups. OSG materials have carbon and hydrogen atoms incorporated into a silicon dioxide lattice, which lowers the dielectric constant of the material.

When etching through the porous silicon oxide for the formation of conductive vias, for example, the plasma and etching chemistry leaves an exposed surface in the silicon oxide which includes exposed pores and which becomes hydrophilic and promotes moisture uptake when exposed to ambient conditions. This has a negative effect on overall circuit capacitance and can provide a source for corrosion for a deposited barrier metal.

### SUMMARY OF THE INVENTION

In accordance with the invention, an exposed surface following an etching process is passivated by forming a self-assembled mono-layer (SAM) on the exposed surface. Advantageously, the exposed pores in an etched surface of a porous low k dielectric material can be filled or sealed by a SAM having a chain link between head group and tail group of sufficient length for assembly by van der Waals force between the chains and a length permitting attachment to the porous surfaces.

In preferred embodiments, an alkyl chlorosilane (—SiC₃) or a hydroxylsilane (—Si(OH)₃) SAM is anchored to the surface of a silicon or a silicon compound such as silicon oxide and including porous organo-silicate-glass (OSG). The alkyl chain can be on the order of 10-20 —CH₂-units, depending on pore size, and preferably 12-18 units in length for present silicon oxide low k dielectric material.

In a plasma etch procedure, after photoresist masking of a surface of a porous silicon oxide layer, a via or a trench is etched through the layer followed by photoresist stripping and cleaning of any etch byproducts. This can be accomplished in a plasma chamber. The material and etched layer are then removed from the plasma chamber and immediately dipped into a solution containing the SAM molecules. A selective chemical reaction causes the SAM molecules to adhere to the exposed surface. For example, an —OH head of the SAM reacts with the exposed SiO₂ while the tail functional group of the SAM, —CH₃ for example, becomes hydrophobic and moisture uptake can be prevented. Moreover, the pores can be effectively sealed by the self-assembled monolayer.

The invention and object and features thereof will be more readily apparent from the following detailed description and appended claims when taken with the drawings.

### BRIEF DESCRIPTION OF THE DRAWINGS

FIG. 1 is a flow diagram of a plasma etching process in accordance with one application of the invention.

FIG. 2A, 2B are section views illustrating a porous silicon oxide insulative layer after plasma etching and after metal deposition, respectively.

FIG. 3 illustrates a SAM alkyl chain adhering to the etched surface of the insulated layer of FIG. 2.

FIG. 4 illustrates in more detail the SAM alkyl chain adhering to the etch surface and the exposed pores in the insulative layer.

FIG. 5 illustrates the head of a SAM chain attached to the exposed SiO2 surface.

### DETAILED DESCRIPTION OF ILLUSTRATIVE EMBODIMENTS

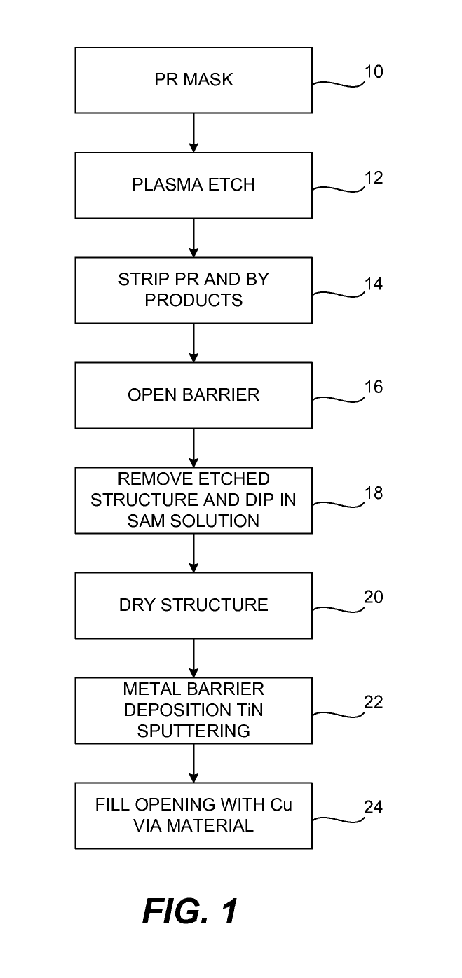

FIG. 1 is a flow diagram of a conventional plasma etching process used in fabricating integrated circuits with stacked metal interconnect layers on the surface of the semiconductor substrate and in which the present invention can be employed. For example, in forming a conductive via or trench from one conductive layer to an underlying conductive layer, a photoresist mask is applied to the stack as shown at 10. The mask covers a top surface of the integrated circuit structure with openings defined therein, through which plasma etching can be employed to remove a dielectric layer between the two metal layers at 12. After the dielectric layer has been etched, the photoresist is stripped and byproducts of the plasma processing are removed at 14.

A barrier layer such as silicon carbide is often employed over a metal layer such as copper to prevent copper ion migration and etch stop. The barrier material must be removed by a second plasma etch at 16 in order to expose the underlying copper metal layer.

Steps 12, 14, 16 can be carried out in a plasma chamber without removal of the etched product. Once the etching processes are completed, the etched structure is removed from the plasma chamber and conventionally moved to a metal depositing chamber for sputtering of a metal barrier layer and the conductive layer for filling the via or trench as shown at 18 and 20. However, the etched structure is particularly susceptible to contamination by moisture uptake, especially for porous silicon oxide material with exposed pores and which becomes hydrophilic and promotes moisture uptake when exposed to ambient conditions.

The conventional process is modified as shown in FIG. 1, by dipping the etched structure in a solution of self-assembled monolayer material as shown at 18 and then drying the structure at 20 before the metal barrier deposition at 22. For silicon and silicon oxide material, preferred SAM materials are alkyl chlorosilane (—SiCO₃) or hydroxylsilane (—Si(OH)₃) in a suitable solvent such as methanol or ethanol.

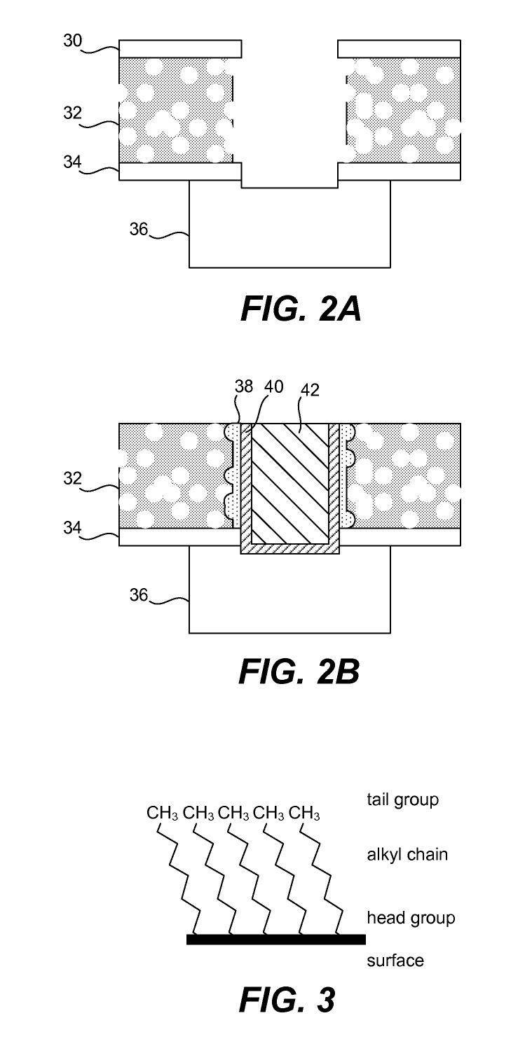

FIG. 2A is a section view of the etched porous low k silicon oxide material prior to dipping in the SAM solution. Here, a hard mask 30 overlies the porous silicon oxide material 32 which rests on an etched silicon carbide barrier material 34 over a copper metal interconnect layer 36. The exposed surface of the porous silicon oxide layer 32 becomes hydrophilic and promotes moisture uptake when the sample is exposed to the ambient condition. As noted above, this has negative effect on overall circuit capacitance and provides a source of corrosion for the barrier metal. Further, it is known that the barrier metal can diffuse into the open and connected porous structure which also lowers overall circuit capacitance. FIG. 2B illustrates the cross-section after removal of the hard mask 30 and formation of a metal contact in the via. A SAM layer 38 covers silicon oxide 32 and covers or seals pores in material 32. A metal barrier layer 40 such as TiN is first sputtered or deposited on the barrier layer and etched layers 34 and 36 and then the via or trench is filled with copper or other metal 42.

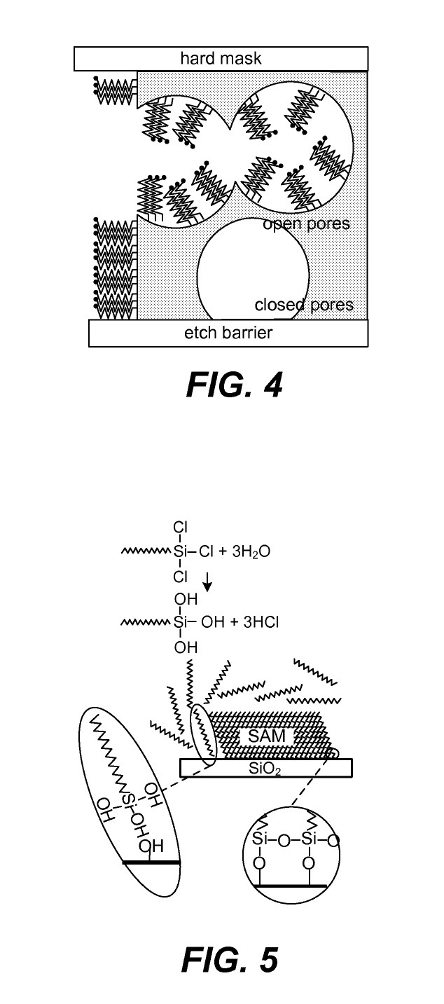

By dipping the etched structure in a SAM solution at 18 in FIG. 1, self-assembled monolayer including a head group, a tail group, and a alkyl chain therebetween attaches to the silicon oxide surface as shown in FIG. 3. The —OH head group combines with the silicon of the porous insulator with the alkyl chain having sufficient length for assembly by van der Waals force to form a self-assembled monolayer. With present porous silicon oxide material, the alkyl chain is preferably 12-18 units in length. By selecting a tail group of —CH₃ termination, overall surface property becomes hydrophobic and moisture uptake is prevented. If the chain link is sufficiently short relative to the size of the pores, the monolayer can attach to the silicon atoms within the pores and effectively fill the pores, as shown in the section view of FIG. 4. Alternatively, if the chains are long relative to the size of the pores, the self-assembled monolayer can cover and effectively seal the pore from exposure to the ambient. FIG. 5 is a sectional view illustrating attachments of the SAM material to the silicon oxide with the silicon atoms sharing oxygen atoms with the OH head group of the monolayer.

Use of a self-assembled monolayer has proved effective in preventing moisture uptake of etched silicon and silicon oxide material and in particular, porous silicon oxide dielectrics. The chain length of the monolayer can be readily tailored for use with pores of increasing size, as is expected in the future.

After forming the monolayer, the SAM molecules on a surface can be further treated with thermal energy or UV radiation which promotes dissociation or bond breakage in the molecule structure. With a desired tail group (for example, metal organic functional groups) these further treatments can deliver the desired elements (metal component only) on the sidewall and inside pore surface of the porous low-k dielectric. It is also possible to select tail groups which can be thermally or photo-activated after forming SAM inside the pores. This further ensures pore sealing by activating cross linking or reactions between the tail groups.

Thus, while the invention has been described with reference to specific embodiments, the description is illustrative of the invention and is not to be construed as limiting the invention. Various modifications and applications may occur to those skilled in the art without departing from the spirit and scope of the invention as defined by the appended claims.

What is claimed is:

1. In the fabrication of integrated circuits where a porous silicon oxide layer is formed over a surface of a semiconductor substrate, a method of surface passivation of a plasma etched surface of the porous silicon oxide layer comprising the steps of:
a) Plasma etching the silicon oxide layer in a plasma etch chamber,
b) Removing the silicon oxide layer from the plasma etch chamber, and
c) Applying a solution of a self-assembled monolayer material to the etched silicon oxide layer thereby forming a protective monolayer on the etched silicon oxide layer.

2. The method of claim 1 wherein the monolayer material has a chain length permitting exposed pores in the etched silicon oxide layer to be filled or sealed by the monolayer material.

3. The method of claim 2 wherein the self-assembled monolayer material comprises a liner alkyl chain molecule including a head that bonds to silicon, a hydrophobic tail, and a plurality of CH₂ chain units.

4. The method of claim 3 wherein the plurality of chain units are sufficient in length for van der Waals force between chains and for at least one of filling and sealing the exposed pores.

5. The method of claim 4 wherein the plurality of chain units are between 10 and 20.

6. The method of claim 5 wherein the plurality of claim units are between 12 and 18.

7. The method of claim 3 wherein the self-assembled monolayer material comprises a hydroxylsilane (—Si(OH)₃) with a —CH₃ termination and a plurality of —CH₂ chain units.

8. The method of claim 7 wherein the plurality of chain units are sufficient in length for van der Waals force between chains and for at least one of filling and sealing the exposed pores.

9. The method of claim 8 wherein the plurality of chain units are between 10 and 20.

10. The method of claim 9 wherein the plurality of chain units are between 12 and 18.

11. The method of claim 1 wherein an opening through the porous silicon oxide layer is formed in step a) and further including the steps of:
d) Drying the porous silicon oxide layer after applying the solution in step c), and
e) Filling the opening with conductive material.

12. The method of claim 1 and further including the steps of:
d) Curing the monolayer to activate cross linking of molecules.

13. In the fabrication of an integrated circuit where a porous silicon oxide layer is formed over a surface of a semiconductor substrate to electrically isolate two conductive metal layers, a structure though the porous silicon oxide layer comprising an opening etched through the porous silicon oxide layer, a self-assembled monolayer adhering to an etched surface of the silicon oxide, and conductive material filling the opening.

14. The structure of claim 13 wherein the monolayer has a chain length permitting exposed pores in the etched silicon oxide layer to be at least one of filled and sealed by the monolayer.

15. The structure of claim 14 wherein the self-assembled monolayer comprises a linear alkyl chain molecule including a head that bonds to silicon, a hydrophobic tail, and a plurality of CH₂ chain units.

16. The structure of claim 15 wherein the self-assembled monolayer comprises an alkyl chlorosilane (—SiCl₃) with a CH₃ termination and a plurality of CH₂ chain units.

17. The structure of claim 16 wherein the plurality of chain units are sufficient in length for van der Waals force between chains and for at least one of filling and sealing the exposed pores.

18. The structure of claim 17 wherein the plurality of chain units are between 10 and 20.

19. The structure of claim 18 wherein the plurality of claim units are between 12 and 18.

20. The structure of claim 15 wherein the self-assembled monolayer comprises a hydroxylsilane (—Si(OH)₃) with a —CH₃ termination and a plurality of —CH₂ chain units.

21. The structure of claim 20 wherein the plurality of chain units are sufficient in length for van der Waals force between chains and for filling or sealing the exposed pores.

22. The structure of claim 21 wherein the plurality of chain units are between 10 and 20.

23. The structure of claim 22 wherein the plurality of chain units are between 12 and 18.

24. The structure of claim 13 wherein the conductive material includes a metal.

25. The structure of claim 24 wherein the metal includes a barrier layer.

26. The structure of claim 25 wherein the barrier layer comprises titanium nitride, the metal includes copper.

27. The structure of claim 13 wherein the porous silicon oxide comprises porous organo-silicate-glass.
